(19) United States
(12) Patent Application Publication
(10) Pub. No.: US 2025/0212509 A1
(43) Pub. Date: Jun. 26, 2025

(54) INTEGRATED CIRCUIT DEVICE

(71) Applicant: Samsung Electronics Co., Ltd., Suwon-si (KR)

(72) Inventors: Sungil PARK, Suwon-si (KR); Jaehyun PARK, Suwon-si (KR)

(73) Assignee: Samsung Electronics Co., Ltd., Suwon-si (KR)

(21) Appl. No.: 18/982,371

(22) Filed: Dec. 16, 2024

(30) Foreign Application Priority Data
Dec. 20, 2023 (KR) 10-2023-0187520

(51) Int. Cl. H10D 84/85; H10D 84/01

(52) U.S. Cl. CPC H10D 84/856; H10D 84/0167; H10D 84/017; H10D 84/0186; H10D 84/851

(57) ABSTRACT

An integrated circuit device may include a first transistor including first nanosheets having a first width in a first horizontal direction, a first gate structure surrounding the of first nanosheets and extending on a first side of the first nanosheets in a second horizontal direction perpendicular to the first horizontal direction, and first source/drain regions on opposite sides of the first nanosheets in the first direction; and a second transistor above the first transistor and including second nanosheets above the first nanosheets and having a second width equal to the first width in the first horizontal direction, a second gate structure surrounding the second nanosheets and on a second side of the second nanosheets in the second horizontal direction, and second source/drain regions on both sides of the second nanosheets in the first horizontal direction.

### CROSS-REFERENCE TO RELATED APPLICATION

This application is based on and claims priority under 35 U.S.C. § 119 to Korean Patent Application No. 10-2023-0187520, filed on Dec. 20, 2023 in the Korean Intellectual Property Office, the disclosure of which is incorporated by reference herein in its entirety.

### BACKGROUND

Inventive concepts relate to an integrated circuit device, and more particularly, to an integrated circuit device including a field-effect transistor.

Recently, as the down-scaling of integrated circuit devices rapidly advances, there may be a need to ensure not only fast operation speed but also operation accuracy in integrated circuit devices. As the degree of integration of integrated circuit devices increases and their size decreases, field-effect transistors with nanosheets are used. Accordingly, there may be a need to develop integrated circuit devices with a new structure that can improve the performance and reliability of nanosheet field-effect transistors.

### SUMMARY

Inventive concepts provide an integrated circuit device able to provide a high degree of integration and improved reliability in nanosheet field-effect transistors.

Aspects of inventive concepts are not limited to those mentioned above, but other aspects not described herein will be clearly understood by those skilled in the art from the following description.

According to an embodiment of inventive concepts, an integrated circuit device may include a first transistor including a plurality of first nanosheets having a first width in a first horizontal direction, a first gate structure surrounding the plurality of first nanosheets and extending on a first side of the plurality of first nanosheets in a second horizontal direction, and first source/drain regions on opposite sides of the plurality of first nanosheets in the first horizontal direction, the second horizontal direction being perpendicular to the first horizontal direction, the first side of the plurality of first nanosheets in the second horizontal direction being opposite a second side of the plurality of first nanosheets in the second horizontal direction; and a second transistor above the first transistor, the second transistor including a plurality of second nanosheets above the plurality of first nanosheets and having a second width in the first horizontal direction, a second gate structure surrounding the plurality of second nanosheets and extending on a second side of the plurality of second nanosheets in the second horizontal direction, and second source/drain regions on opposite sides of the plurality of second nanosheets in the first horizontal direction, the second width being equal to the first width, the second side of the plurality of second nanosheets in the second horizontal direction being opposite a first side of the plurality of second nanosheets in the second horizontal direction, and the second side of the plurality of second nanosheets in the second horizontal direction being over the second side of the plurality of first nanosheets in the second horizontal direction.

According to an embodiment of inventive concepts, an integrated circuit device may include a lower transistor; and an upper transistor at a higher vertical level than the lower transistor. The lower transistor may include lower source/drain regions and a lower gate structure between the lower source/drain regions. The upper transistor may include upper source/drain regions and an upper gate structure between the upper source/drain regions. The lower gate structure and the upper gate structure may divide and share a plurality of nanosheets into an upper portion and a lower portion. The plurality of nanosheets may be stacked in a vertical direction and have aligned centers.

According to an embodiment of inventive concepts, an integrated circuit device may include two first transistors spaced apart from each other in a first horizontal direction; two second transistors spaced apart from each other in the first horizontal direction, the second transistors being above the two first transistors; and two third transistors spaced apart from each other in the first horizontal direction with the two first transistors and the two second transistors therebetween. Each of the two first transistors may include a plurality of first nanosheets having a first width in the first horizontal direction, a first gate structure surrounding the plurality of first nanosheets and extending on a first side of the plurality of first nanosheets in a second horizontal direction, and first source/drain regions on opposite sides of the plurality of first nanosheets in the first horizontal direction. The second horizontal direction may be perpendicular to the first horizontal direction. The first side of the plurality of first nanosheets in the second horizontal direction may be opposite a second side of the plurality of first nanosheets in the second horizontal direction. Each of the two second transistors may include a plurality of second nanosheets above an underlying one of the plurality of first nanosheets and having a second width in the first horizontal direction, a second gate structure surrounding the plurality of second nanosheets and extending on a second side of the plurality of second nanosheets in the second horizontal direction, and second source/drain regions on opposite sides of the plurality of second nanosheets in the first horizontal direction. The second width may be equal to the first width. The second side of the plurality of second nanosheets in the second horizontal direction may be opposite a first side of the plurality of second nanosheets in the second horizontal direction. The second side of the plurality of second nanosheets in the second horizontal direction may be over the second side of the underlying one of plurality of first nanosheets in the second horizontal direction. Each of the two third transistors may include a plurality of third nanosheets having a third width equal to the first width in the first horizontal direction, a third gate structure surrounding the plurality of third nanosheets and extending on one side of the plurality of third nanosheets in the second horizontal direction, and third source/drain regions on both sides of the plurality of third nanosheets.

### BRIEF DESCRIPTION OF THE DRAWINGS

Embodiments will be more clearly understood from the following detailed description taken in conjunction with the accompanying drawings in which:

FIG. 1 is a plan view schematically illustrating an integrated circuit device according to an embodiment;

FIG. 2 is a cross-sectional view of the integrated circuit device of FIG. 1 taken along line A-A;

FIG. 3 is a cross-sectional view of the integrated circuit device of FIG. 1 taken along line B-B;

FIG. 4 is a cross-sectional view of the integrated circuit device of FIG. 1 taken along line C-C;

FIG. 5 is a circuit diagram illustrating an integrated circuit device according to an embodiment;

FIG. 6 is a front-side layout view illustrating the integrated circuit device of FIG. 5;

FIG. 7 is a back-side layout view illustrating the integrated circuit device of FIG. 5;

FIG. 8 is cross-sectional views of the integrated circuit device of FIGS. 6 and 7 taken along lines X1-X2 and X3-X4;

FIG. 9 is cross-sectional views of the integrated circuit device of FIGS. 6 and 7 taken along lines Y1-Y2 and Y3-Y4; and

FIGS. 10 to 30 are cross-sectional views illustrating a method of manufacturing an integrated circuit device in a process sequence, according to an embodiment.

### DETAILED DESCRIPTION

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, an embodiment is described in detail with reference to the accompanying drawings.

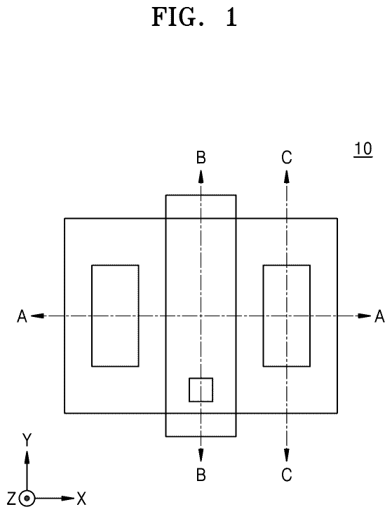

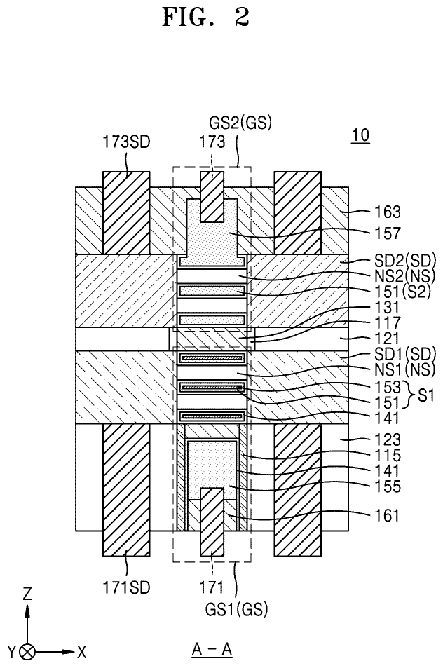

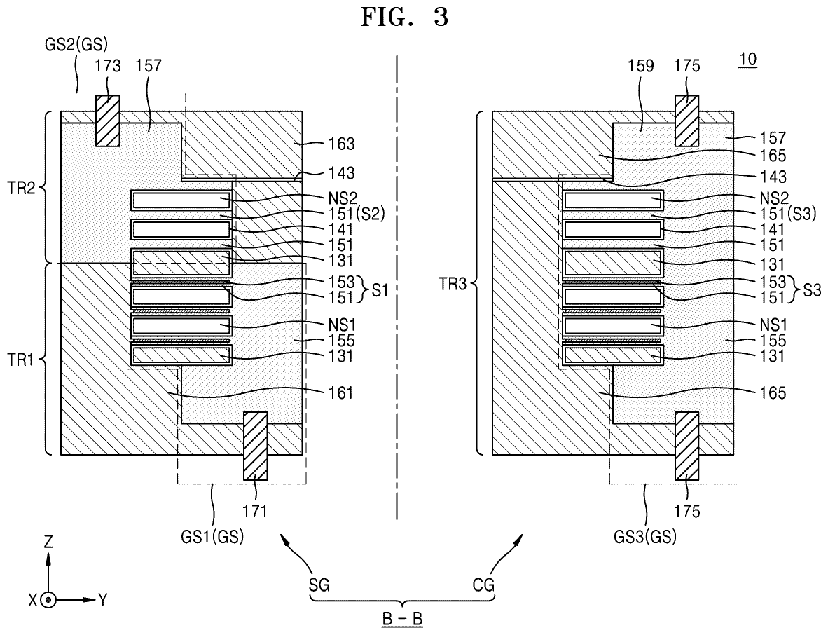

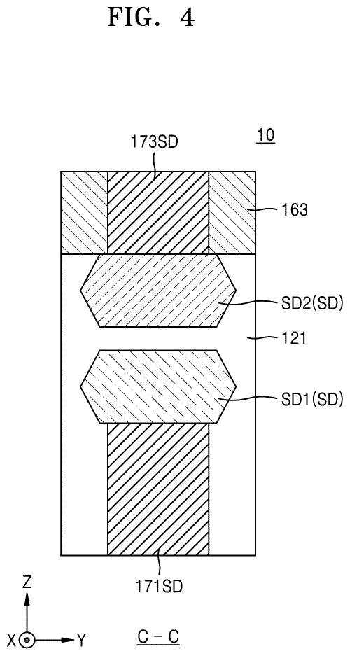

FIG. 1 is a plan view schematically illustrating an integrated circuit device according to an embodiment. FIG. 2 is a cross-sectional view of the integrated circuit device of FIG. 1 taken along line A-A. FIG. 3 is a cross-sectional view of the integrated circuit device of FIG. 1 taken along line B-B. FIG. 4 is a cross-sectional view of the integrated circuit device of FIG. 1 taken along line C-C.

For ease of describing and understanding, one plan view is illustrated as a representative. However, depending on positions in an integrated circuit device 10, a cross-sectional view taken along line B-B as illustrated in FIG. 3 may illustrate a split gate region SG or a common gate region CG.

In addition, although it would be a correct illustration not to show a first gate contact 171 and a second gate contact 173 in FIG. 2 since the first gate contact 171 and the second gate contact 173 are not located on a cross-section but in a diagonal direction, the first gate contact 171 and the second gate contact 173 are illustrated together for ease of describing and understanding.

Referring to FIGS. 1 to 4 together, the integrated circuit device 10 according to an embodiment may include a plurality of first to third transistors TR1, TR2, and TR3, and each of the plurality of first to third transistors TR1, TR2, and TR3 may constitute a logic cell including a multi-bridge channel field-effect transistor (MBCFET).

The integrated circuit device 10 according to the embodiment may have a constant unit area in a first horizontal direction (an X direction) and a second horizontal direction (a Y direction) perpendicular to the first horizontal direction (the X direction). The integrated circuit device 10 may include a plurality of nanosheets NS, a gate structure GS, source/drain regions SD, and a gate dielectric film 141.

The plurality of nanosheets NS may include a semiconductor pattern having relatively large widths in the first horizontal direction (the X direction) and the second horizontal direction (the Y direction) and having a relatively small thickness in a vertical direction (a Z direction). For example, the plurality of nanosheets NS may have a width ranging from about 5 nm to about 100 nm and a thickness ranging from about 1 nm to about 10 nm, but an embodiment is not limited thereto. Each of the plurality of nanosheets NS may be an active nanosheet and may function as a channel region.

The gate structure GS may be formed to surround the plurality of nanosheets NS. In some embodiments, the gate structure GS may include doped polysilicon, metal, conductive metal nitride, conductive metal carbide, conductive metal silicide, or a combination thereof. For example, the gate structure GS may include Al, Cu, Ti, Ta, W, Mo, TaN, NiSi, CoSi, TiN, WN, TiAl, TiAlN, TaCN, TaC, TaSiN, or a combination thereof, but an embodiment is not limited thereto.

The source/drain regions SD may be connected to both ends of the plurality of nanosheets NS with respect to the gate structure GS. The source/drain regions SD may include an epitaxial layer doped with impurities such as boron (B), arsenic (As), or phosphorus (P). The source/drain regions SD may include a silicon (Si) epitaxial layer or a silicon germanium (SiGe) epitaxial layer.

The gate dielectric film 141 may be located between the gate structure GS and the plurality of nanosheets NS. In some embodiments, the gate dielectric film 141 may include silicon oxide, silicon oxynitride, a high-k dielectric material having a higher dielectric constant than silicon oxide, or a combination thereof. The high-k dielectric material may include metal oxide or metal oxynitride. For example, the high-k dielectric material that may be used as the gate dielectric film 141 may include HfO, HfSiO, HfSiON, HfTaO, HfTiO, HfZrO, ZrO, AlO, or a combination thereof, but an embodiment is not limited thereto.

The integrated circuit device 10 according to an embodiment may include a first transistor TR1 and a second transistor TR2 that are stacked in the split gate region SG in the vertical direction (the Z direction) and a third transistor TR3 spaced apart from the first transistor TR1 and the second transistor TR2 in the first horizontal direction (the X direction) and located in the common gate region CG.

First, the first transistor TR1 and the second transistor TR2 that are stacked and located in the split gate region SG of the integrated circuit device 10 are illustrated.

In some embodiments, the first transistor TR1 and the second transistor TR2 may be different types of transistors. For example, the first transistor TR1 may include an n-channel metal-oxide semiconductor (NMOS) transistor and the second transistor TR2 may include a p-channel metal-oxide semiconductor (PMOS) transistor. However, an embodiment is not limited thereto, the first transistor TR1 may include a PMOS transistor and the second transistor TR2 may include an NMOS transistor.

In some embodiments, the plurality of nanosheets NS may include a plurality of first nanosheets NS1 and a plurality of second nanosheets NS2 that are spaced apart from each other in the vertical direction (the Z direction). A dummy nanosheet 131 may be located between the plurality of first nanosheets NS1 and the plurality of second nanosheets NS2. In addition, the dummy nanosheet 131 may be also located under the plurality of first nanosheets NS1. Here, the dummy nanosheet 131 may refer to a structure that has a shape of a nanosheet but does not operate. That is, the dummy nanosheet 131 may be understood as the opposite of an active nanosheet.

In some embodiments, the source/drain regions SD may include first source/drain regions SD1 and second source/drain regions SD2 that are spaced apart from each other in the vertical direction (the Z direction). In addition, a side wall separation layer 117 and a first separation layer 121 may be located between the first source/drain regions SD1 and the second source/drain regions SD2. The side wall separation layer 117 and the first separation layer 121 may include different insulating materials. Here, the first source/drain regions SD1 may include first source/drain contacts 171SD in contact with a lower portion thereof. In addition, the second source/drain regions SD2 may include second source/drain contacts 173SD in contact with an upper portion thereof.

In some embodiments, the gate structure GS may include a first gate structure GS1 and a second gate structure GS2 that are spaced apart from each other in the vertical direction (the Z direction).

In the first transistor TR1, the first gate structure GS1 may include a plurality of first sub-gates S1 surrounding the plurality of first nanosheets NS1 and a first main gate 155 contacting the plurality of first sub-gates S1 and extending on one side (e.g., +Y side) in the second horizontal direction (the Y direction). In addition, the first gate structure GS1 may include a first gate contact 171 in contact with a lower portion of the first main gate 155. Here, the plurality of first sub-gates S1 may include double conductive material films 151 and 153 including different materials.

In a cross-sectional view of FIG. 3, in a side portion of the first gate structure GS1, a first insulating layer 161 may be located and have a thickness that is greater than the thickness of the first gate structure GS1 in the vertical direction (the Z direction). In addition, in an upper portion of the first gate structure GS1, a second insulating layer 163 may be located and have a thickness that is greater than the thickness of the second gate structure GS2 in the vertical direction (the Z direction). In some embodiments, the dummy nanosheet 131 may be located under a lowermost first sub-gate S1 among the plurality of first sub-gates S1.

A spacer 115 may be located on both side walls of the first gate structure GS1. The spacer 115 may include silicon oxide, silicon nitride, silicon oxynitride, silicon carbonitride, silicon oxide carbonitride, or a combination thereof.

The first source/drain regions SD1 may be located at both ends of the plurality of first nanosheets NS1, and lower surfaces of the first source/drain contacts 171SD in contact with the lower portion of the first source/drain regions SD1 may be at the same vertical level as a lower surface of the first gate contact 171.

In the second transistor TR2, the second gate structure GS2 may include a plurality of second sub-gates S2 surrounding the plurality of second nanosheets NS2 and a second main gate 157 contacting the plurality of second sub-gates S2 and extending on the other side (e.g., −Y side) in the second horizontal direction (the Y direction). In addition, the second gate structure GS2 may include a second gate contact 173 in contact with an upper portion of the second main gate 157. Here, the plurality of second sub-gates S2 may each include a single conductive material film 151 including the same material.

In the cross-sectional view of FIG. 3, on a side portion of the second gate structure GS2, the second insulating layer 163 may be located and have a thickness that is greater than the thickness of the second gate structure GS2 in the vertical direction (the Z direction). In addition, on a lower portion of the second gate structure GS2, the first insulating layer 161 may be located and have a thickness that is greater than the thickness of the first gate structure GS1 in the vertical direction (the Z direction). In some embodiments, an insulating pattern layer 143 including the same material as the gate dielectric film 141 may be located to extend from an upper surface of an uppermost second sub-gate S2 among the plurality of second sub-gates S2 to the inside of the second insulating layer 163. This may be a feature resulting from a manufacturing method described below of the integrated circuit device 10, according to an embodiment.

The second source/drain regions SD2 may be located at both ends of the plurality of second nanosheets NS2, and an upper surface of the second source/drain contacts 173SD in contact with an upper portion of the second source/drain regions SD2 may be at the same level as an upper surface of the second gate contact 173.

In the cross-sectional view of FIG. 3, the first main gate 155 of the first gate structure GS1 constituting the first transistor TR1 may be in a diagonal direction to the second main gate 157 of the second gate structure GS2 constituting the second transistor TR2. In addition, the first gate contact 171 may be in a diagonal direction to the second gate contact 173. That is, the first gate structure GS1 and the second gate structure GS2 may be respectively located in an upper portion and a lower portion with respect to the dummy nanosheet 131 between the plurality of first nanosheets NS1 and the plurality of second nanosheets NS2.

Next, the third transistor TR3 located in the common gate region CG of the integrated circuit device 10 is described.

In some embodiments, the plurality of nanosheets NS may include the plurality of first nanosheets NS1 and the plurality of second nanosheets NS2 that are spaced apart from each other in the vertical direction (the Z direction). The dummy nanosheet 131 may be located between the plurality of first nanosheets NS1 and the plurality of second nanosheets NS2. In addition, the dummy nanosheet 131 may be also located under the plurality of first nanosheets NS1.

Here, the third transistor TR3 may use both the plurality of first nanosheets NS1 and the plurality of second nanosheets NS2 as channel regions. That is, when referring to the channel regions as a plurality of third nanosheets in the third transistor TR3, a vertical level of an uppermost surface of the plurality of third nanosheets may be the same as a vertical level of an uppermost surface of the plurality of second nanosheets NS2 and a vertical level of a lowermost surface of the plurality of third nanosheets may be the same as a vertical level of a lowermost surface of the plurality of first nanosheets NS1.

In some embodiments, the gate structure GS may include a third gate structure GS3 extending in the vertical direction (the Z direction).

In the third transistor TR3, the third gate structure GS3 may include a plurality of third sub-gates S3 surrounding the plurality of nanosheets NS and a third main gate 159 contacting the plurality of third sub-gates S3 and extending on the one side (e.g., the +Y side) in the second horizontal direction (the Y direction). In addition, the third gate structure GS3 may include third gate contacts 175 in contact with lower and upper portions of the third main gate 159. Ther third gate contacts 175 may be located on a straight line in the vertical direction (the Z direction). Here, some of the plurality of third sub-gates S3 may include the double conductive material films 151 and 153 including different materials.

In the cross-sectional view of FIG. 3, on a side portion of the third gate structure GS3, a third insulating layer 165 may be located and have a thickness that is greater than the thickness of the third gate structure GS3 in the vertical direction (the Z direction). In some embodiments, the dummy nanosheet 131 may be located under a lowermost third sub-gate S3 among the plurality of third sub-gates S3. In some embodiments, the insulating pattern layer 143 including the same material as the gate dielectric film 141 may be located to extend from an upper surface of an uppermost third sub-gate S3 among the plurality of third sub-gates S3 to the inside of the third insulating layer 165. This may be a feature resulting from a manufacturing method described below of the integrated circuit device 10, according to an embodiment.

In some embodiments, a vertical level of an uppermost surface of the third gate structure GS3 may be the same as a vertical level of an uppermost surface of the second gate structure GS2, and a vertical level of a lowermost surface of the third gate structure GS3 may be the same as a vertical level of a lowermost surface of the first gate structure GS1.

In the integrated circuit device 10 according to an embodiment, a three-dimensional vertical stacked structure in which the first transistor TR1 and the second transistor TR2 are stacked in the vertical direction (the Z direction) may be used and the third transistor TR3 that is single may be used in the vertical direction (the Z direction). Accordingly, the integrated circuit device 10 may provide a high degree of integration due to a decrease in unit area, may reduce capacitance between a gate structure and a gate contact, and may thus have improved electrical properties.

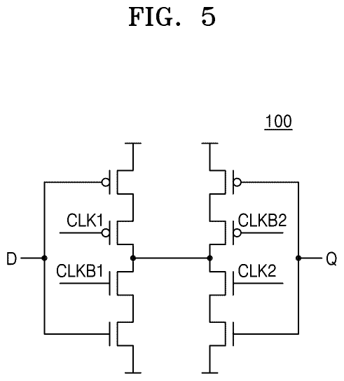

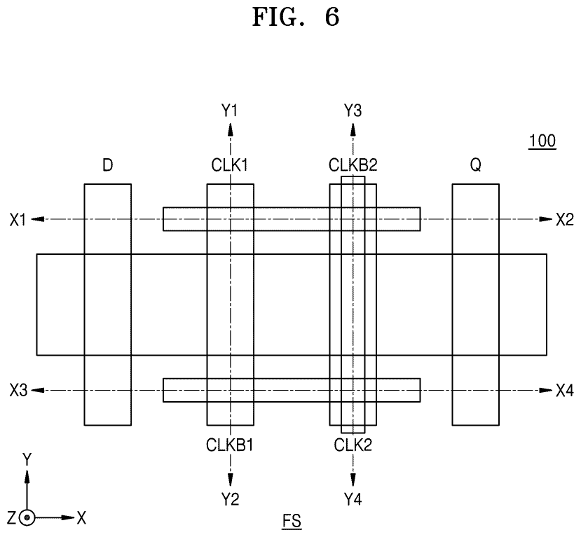

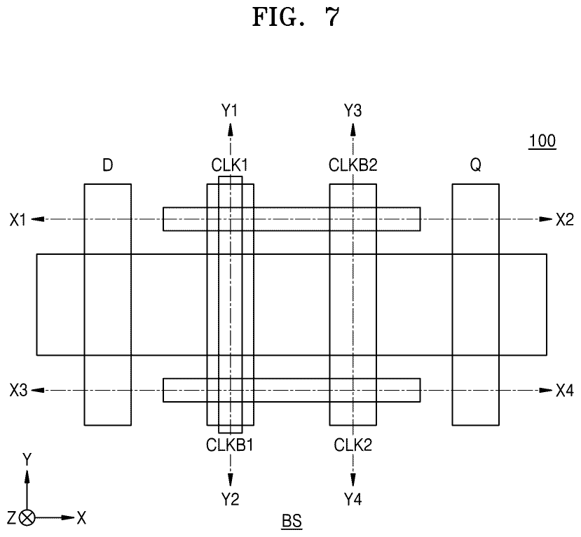

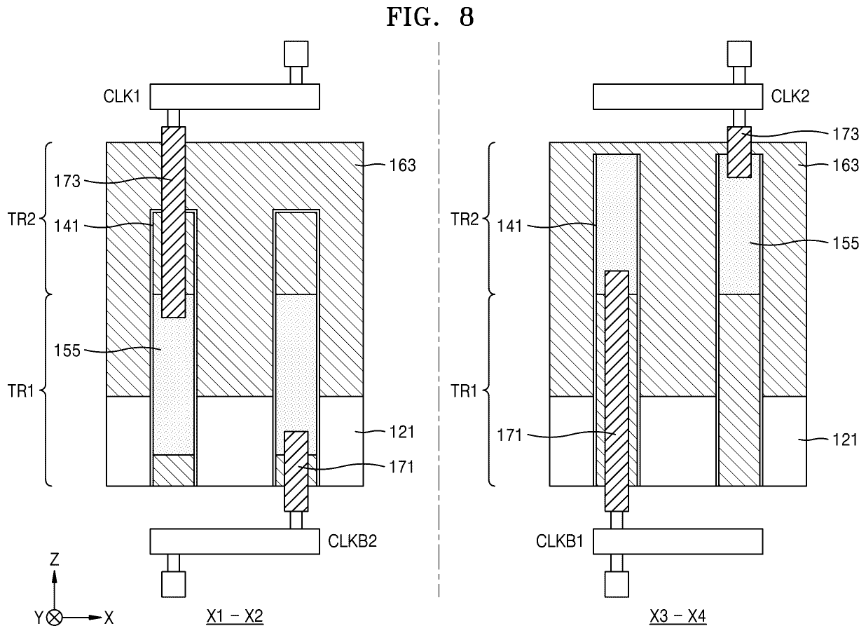

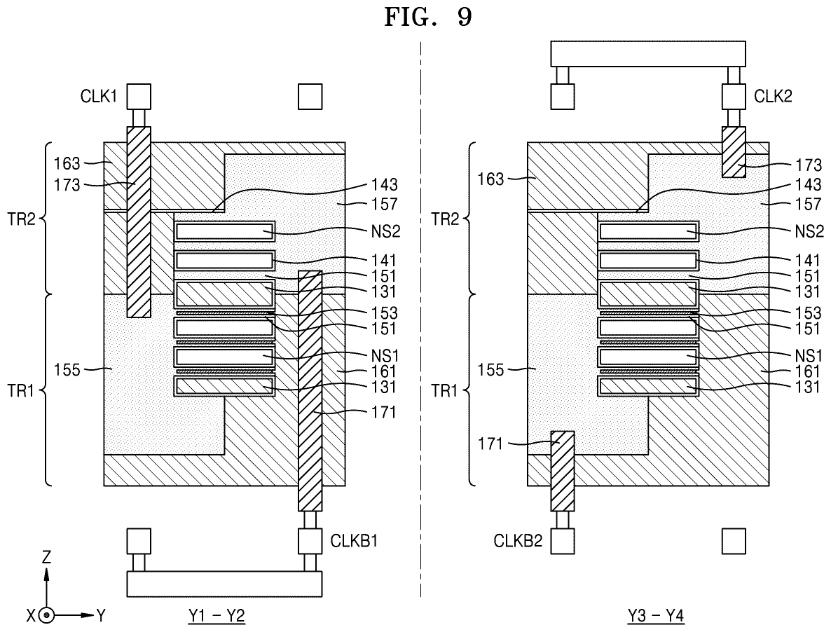

FIG. 5 is a circuit diagram illustrating an integrated circuit device according to an embodiment. FIG. 6 is a front-side layout view illustrating the integrated circuit device of FIG. 5. FIG. 7 is a back-side layout view illustrating the integrated circuit device of FIG. 5. FIG. 8 is cross-sectional views of the integrated circuit device of FIGS. 6 and 7 taken along lines X1-X2 and X3-X4. FIG. 9 is cross-sectional views of the integrated circuit device of FIGS. 6 and 7 taken along lines Y1-Y2 and Y3-Y4.

Referring to FIGS. 5 to 9 together, an integrated circuit device 100 may have a flip-flop structure including six transistors to operate.

Most of components forming the integrated circuit device 100 described below and materials forming the components are substantially the same as or similar to those described above with reference to FIGS. 1 to 4. Therefore, for convenience of description, the description focuses on the differences from the integrated circuit device 10 described above. The notion that elements are “substantially the same” may indicate that the element may be completely the same and may also indicate that the elements may be determined to be the same in consideration of errors or deviations occurring during a process.

The integrated circuit device 100 may include two first transistors TR1, two second transistors TR2 stacked above the two first transistors TR1, and two third transistors TR3 (see FIG. 3) having the two first transistors TR1 and the two second transistors TR2 therebetween. Here, the two first transistors TR1 may include NMOS transistors and the two second transistors TR2 may include PMOS transistors, but an embodiment is not limited thereto.

In some embodiments, in the integrated circuit device 100, one of the two first transistors TR1 may correspond to a first inner clock CLK1 and one of the two second transistors TR2 may correspond to a second inner clock CLK2. In addition, the other of the two first transistors TR1 may correspond to a first inner inverted clock CLKB1 and the other of the two second transistors TR2 may correspond to a second inner inverted clock CLKB2. In addition, any one of the two third transistors TR3 (see FIG. 3) may correspond to a first signal D, and the other of the two third transistors TR3 (FIG. 3) may correspond to a second signal Q.

The integrated circuit device 100 according to inventive concepts may provide the flip-flop structure by using the three-dimensional vertical stacked structure in which NMOS transistors and PMOS transistors are stacked in the vertical direction (the Z direction) and may thus have a high degree of integration and improved electrical properties.

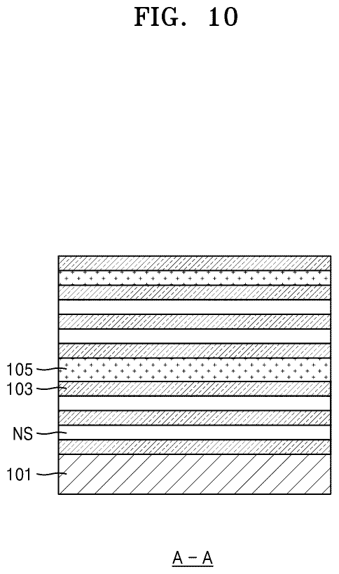

FIGS. 10 to 30 are cross-sectional views illustrating a method of manufacturing an integrated circuit device in a process sequence, according to an embodiment.

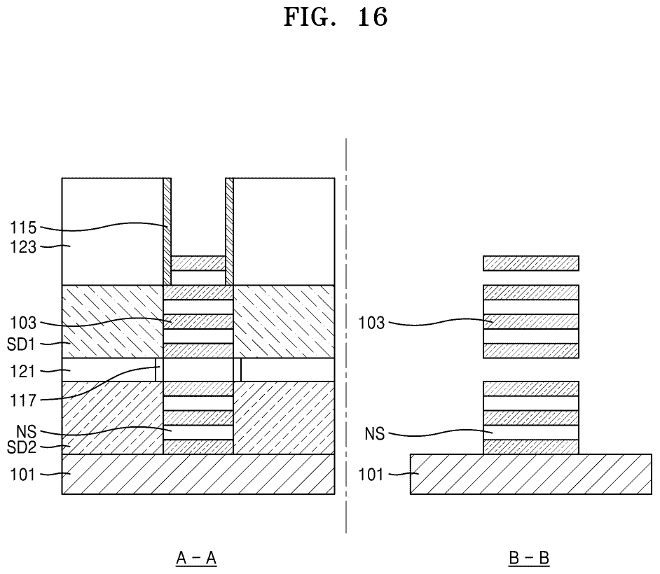

For ease of describing and understanding, FIGS. 10 to 15 are cross-sectional views corresponding to a cross-section taken along line A-A of FIG. 1, and FIGS. 16 to 30 are cross-sectional views corresponding together to cross-sections taken along lines A-A and B-B of FIG. 1.

Referring to FIG. 10, sacrificial layers 103 and nanosheets NS may be alternately formed on a substrate 101.

In some embodiments, the sacrificial layers 103 and the nanosheets NS may be formed by an epitaxial process. Additionally, the sacrificial layers 103 and the nanosheets NS may include materials having etch selectivity with respect to each other. For example, each of the sacrificial layers 103 and the nanosheets NS may include a single crystal layer of a group IV semiconductor, a group IV-IV compound semiconductor, or a group III-V compound semiconductor, and the sacrificial layer 103 and the nanosheet NS may include different materials. For example, the sacrificial layer 103 may include silicon germanium (SiGe) and the nanosheet NS may include single crystalline silicon.

In some embodiments, the epitaxial process may include a chemical vapor deposition (CVD) process such as vapor-phase epitaxy (VPE) and ultra-high vacuum chemical vapor deposition (UHV-CVD), molecular beam epitaxy, or a combination thereof. In the epitaxial process, a liquid or gaseous precursor may be used as a precursor for forming the sacrificial layer 103 and the nanosheet NS.

Here, dummy sacrificial layers 105 other than the nanosheet NS may be partially formed between the sacrificial layers 103. In some embodiments, the sacrificial layer 103 may include silicon germanium (SiGe) with a relatively low concentration of germanium (Ge), and each of the dummy sacrificial layers 105 may include silicon germanium (SiGe) with a relatively high concentration of germanium (Ge).

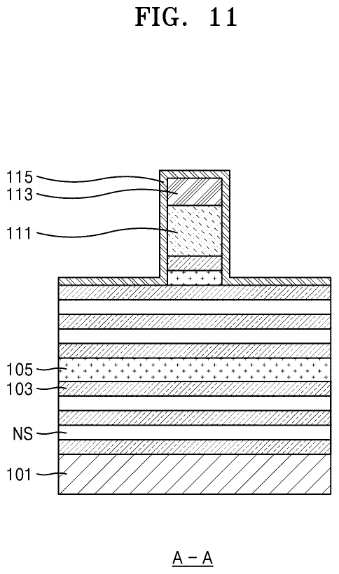

Referring to FIG. 11, sacrificial mask patterns 111 and 113 may be formed on an uppermost sacrificial layer 103, and then the sacrificial layers 103 and the dummy sacrificial layers 105 may be patterned using the sacrificial mask patterns 111 and 113 as an etching mask.

In some embodiments, the sacrificial mask patterns 111 and 113 may include a first sacrificial mask pattern 111 including polysilicon and a second sacrificial mask pattern 113 including silicon nitride.

Next, a spacer 115 may be formed so as to conformally cover side walls and an upper surface of the sacrificial layers 103, side walls of the dummy sacrificial layer 105, and side walls and an upper surface of the sacrificial mask patterns 111 and 113. For example, the spacer 115 may include at least one material selected from among thermal oxide, silicon oxide, and silicon nitride.

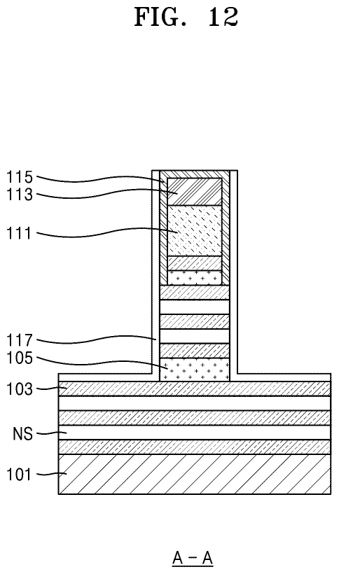

Referring to FIG. 12, the sacrificial layers 103, the dummy sacrificial layers 105, and the nanosheets NS may be patterned using the side walls of the sacrificial mask patterns 111 and 113 and the spacer 115 as an etching mask.

Next, a side wall separation layer 117 may be formed so as to cover side walls and the upper surface of the sacrificial layers 103, side walls of the dummy sacrificial layers 105, and the side walls of the spacer 115. The side wall separation layer 117 may include an insulating material that is different from the material of the spacer 115.

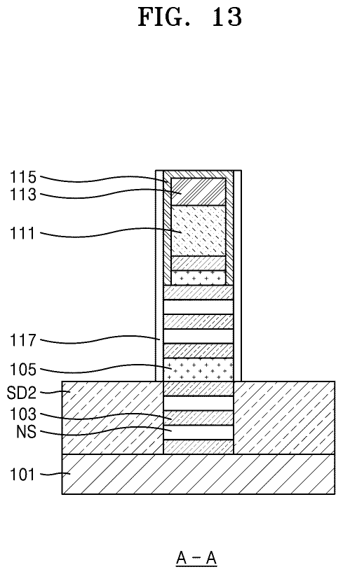

Referring to FIG. 13, the sacrificial layers 103 and the nanosheets NS may be patterned using the side walls of the sacrificial mask patterns 111 and 113, the side walls of the spacer 115, and side walls of the side wall separation layer 117 as an etching mask, and, therefore, an upper surface of the substrate 101 may be exposed.

Next, second source/drain regions SD2 may be formed on the exposed upper surface of the substrate 101 using an epitaxial process and using both side walls, which are exposed, of the sacrificial layers 103 and the nanosheets NS as seed layers.

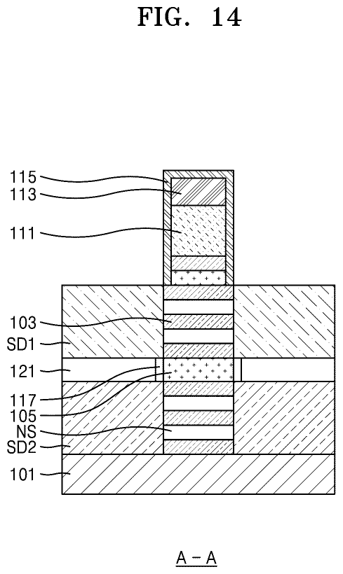

Referring to FIG. 14, an etching process of leaving the side wall separation layer 117 only on side walls, which are exposed, of the dummy sacrificial layer 105 may be performed and a first separation layer 121 may be formed on an upper portion of the second source/drain regions SD2.

Although not shown, first, a vertical level of an uppermost surface of the first separation layer 121 may be formed to be at the same level as a vertical level of an uppermost surface of the spacer 115. For example, the first separation layer 121 may include any one material selected from among silicon oxide and silicon oxynitride.

Next, a portion of the first separation layer 121 may be etched and a recess region (not shown) may be formed. Accordingly, both of the side walls of the sacrificial layers 103 and the nanosheets NS may be exposed.

Next, first source/drain regions SD1 may be formed while filling the recess region using an epitaxial process and using both of the exposed side walls of the sacrificial layers 103 and the nanosheets NS as seed layers.

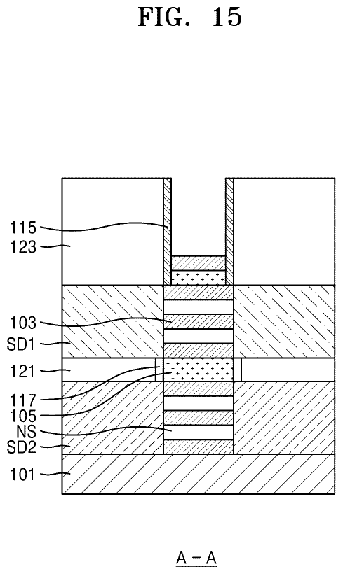

Referring to FIG. 15, a second separation layer 123 may be formed on an upper portion of the first source/drain regions SD1.

The second separation layer 123 may include substantially the same material as the first separation layer 121. For example, the second separation layer 123 may include any one material selected from among silicon oxide and silicon oxynitride.

Next, the uppermost surface of the spacer 115 may be etched and the sacrificial mask patterns 111 and 113 (see FIG. 14) that are exposed due to the etching may be removed. Accordingly, an uppermost surface of the nanosheets NS may be exposed.

Referring to FIG. 16, the dummy sacrificial layers 105 (see FIG. 15) may be entirely removed from between the sacrificial layers 103.

The dummy sacrificial layers 105 may be entirely removed without removing the sacrificial layers 103 by using etch selectivity of the sacrificial layer 103 and the dummy sacrificial layer 105. Accordingly, an empty space may be formed between some sacrificial layers 103.

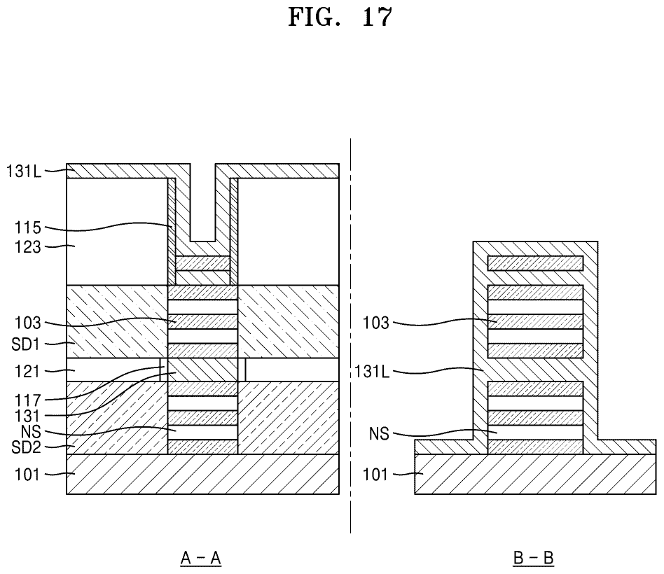

Referring to FIG. 17, a dummy nanosheet layer 131L may be formed so as to surround the sacrificial layers 103 and the nanosheets NS and conformally cover the spacer 115 and the second separation layer 123.

The dummy nanosheet layer 131L may include an insulating material and, for example, may include at least one material selected from among silicon oxide, silicon nitride, and silicon oxynitride.

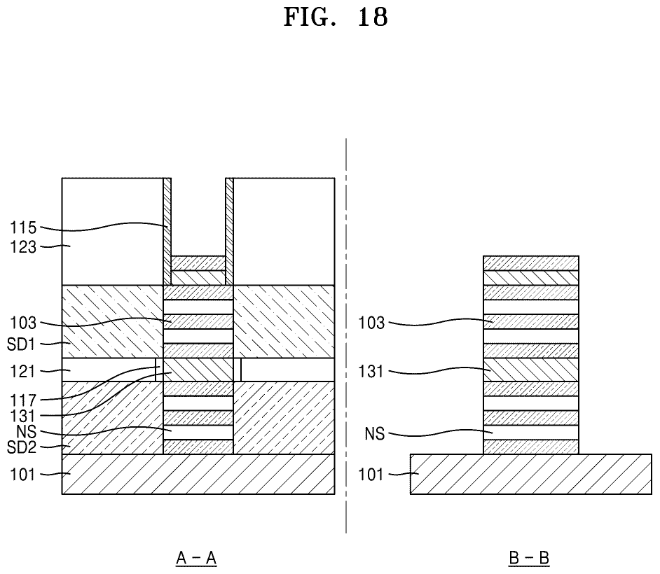

Referring to FIG. 18, dummy nanosheets 131 may be formed at positions at which the dummy sacrificial layers 105 (see FIG. 15) were located.

Specifically, the dummy nanosheet layer 131L (see FIG. 17) may be patterned and the dummy nanosheets 131 may be formed between the sacrificial layers 103. That is, the dummy sacrificial layers 105 may be replaced with the dummy nanosheets 131 at the same positions through a replacement process.

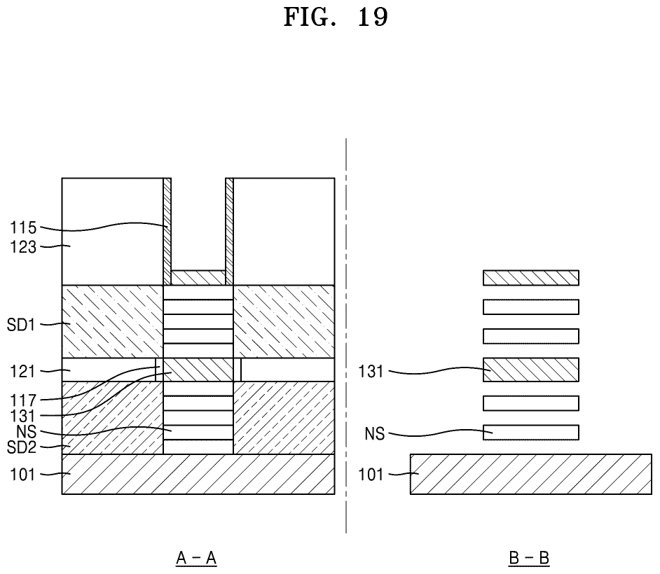

Referring to FIG. 19, the sacrificial layers 103 (see FIG. 18) may be entirely removed from between the nanosheets NS and/or the dummy nanosheets 131.

The sacrificial layers 103 may be entirely removed without removing the nanosheets NS and the dummy nanosheets 131 by using etch selectivity of the nanosheet NS and the sacrificial layer 103 and etch selectivity of the dummy nanosheet 131 and the sacrificial layer 103. Accordingly, an empty space may be formed between the nanosheets NS and/or the dummy nanosheets 131.

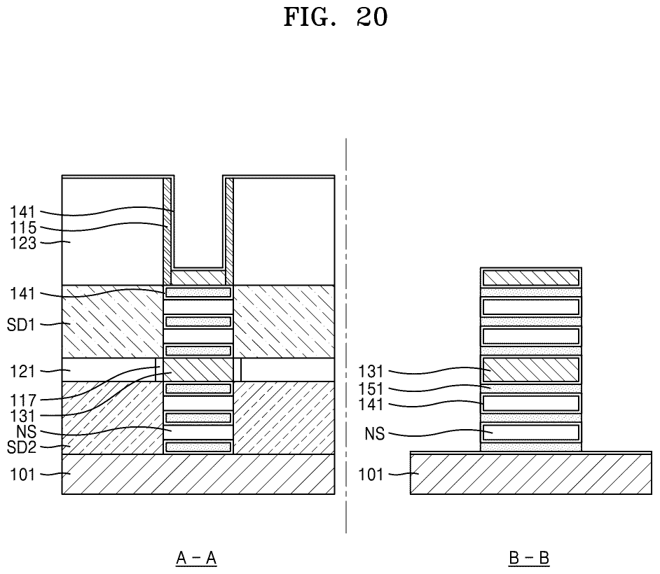

Referring to FIG. 20, gate dielectric films 141 may be formed so as to surround exposed surfaces of the nanosheets NS and the dummy nanosheets 131.

Next, conductive material films 151 may be formed on the gate dielectric films 141 so as to fill spaces between the nanosheets NS and/or the dummy nanosheets 131.

The conductive material films 151 may be referred to as a buried conductive film. Each of the conductive material films 151 may include, for example, doped polysilicon, metal, conductive metal nitride, conductive metal carbide, conductive metal silicide, or a combination thereof.

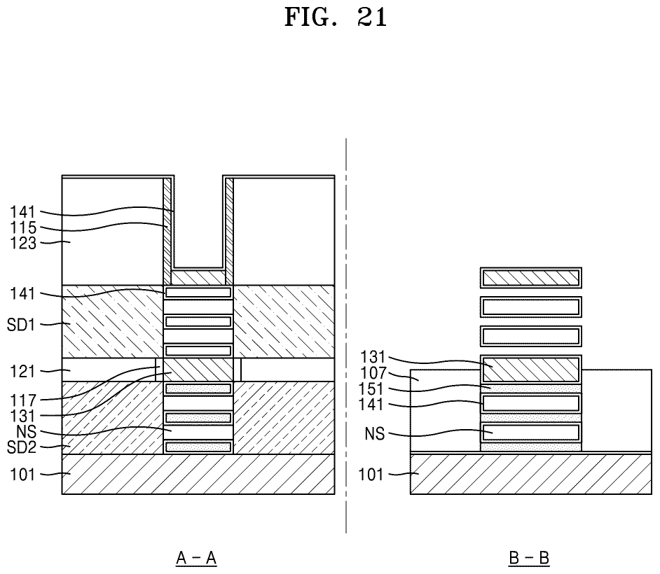

Referring to FIG. 21, a lower sacrificial layer 107 may be formed so as to cover a portion of a middle dummy nanosheet 131 and a lower region thereof.

Next, exposed conductive material films 151 may be removed. Conductive material films 151 located in the lower region of the middle dummy nanosheet 131 may be protected due to the lower sacrificial layer 107, and conductive material films 151 located in an upper region of the middle dummy nanosheet 131 may be entirely removed.

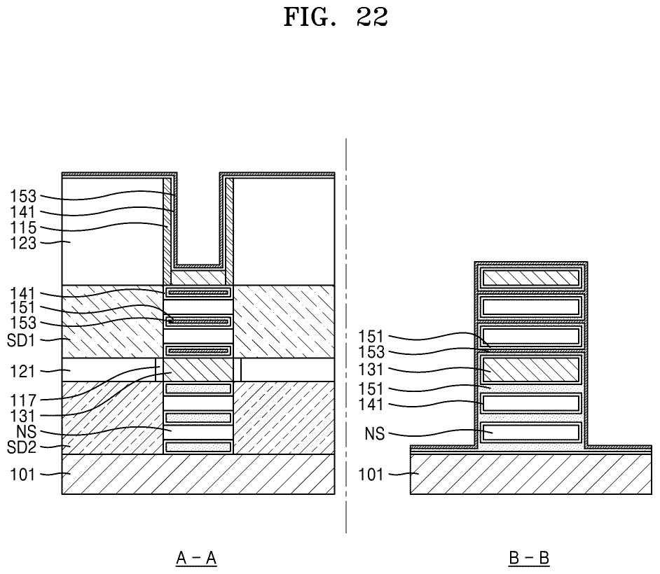

Referring to FIG. 22, the lower sacrificial layer 107 (see FIG. 21) may be removed, and double conductive material films 151 and 153 may be formed at positions, at which the conductive material films 151 have been removed so as to surround the nanosheets NS and the dummy nanosheets 131.

The double conductive material films 151 and 153 may include different conductive materials such as doped polysilicon and conductive metal nitride.

Through the process described above, with respect to the middle dummy nanosheet 131, the double conductive material films 151 and 153 may be located in the upper region of the middle dummy nanosheet 131, and the single conductive material films 151 may be located in the lower region of the middle dummy nanosheet 131.

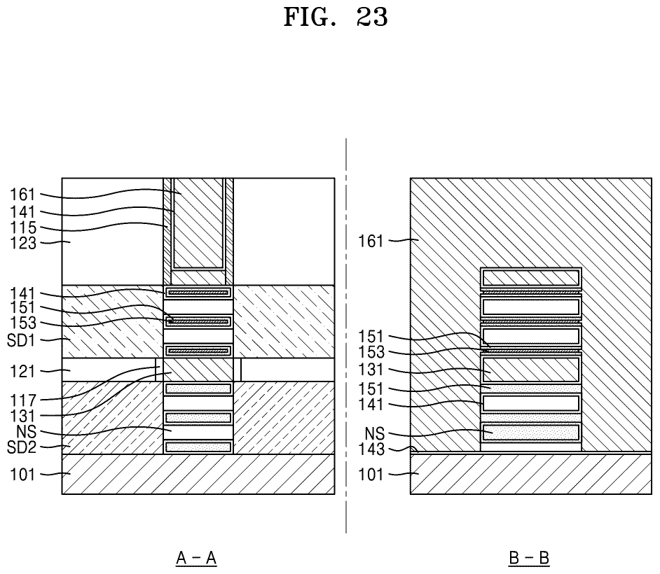

Referring to FIG. 23, a first insulating layer 161 may be formed so as to surround an inner space, in which the sacrificial mask patterns 111 and 113 (see FIG. 14) have been removed, of the spacer 115, the nanosheets NS, the dummy nanosheets 131, the conductive material films 151, and the double conductive material films 151 and 153.

The first insulating layer 161 may include silicon nitride, but an embodiment is not limited thereto. Next, an upper surface of the first insulating layer 161 may be polished, and thus an upper surface of the second separation layer 123 may be exposed. In the polishing process, the second separation layer 123 may be used as an etch stop film.

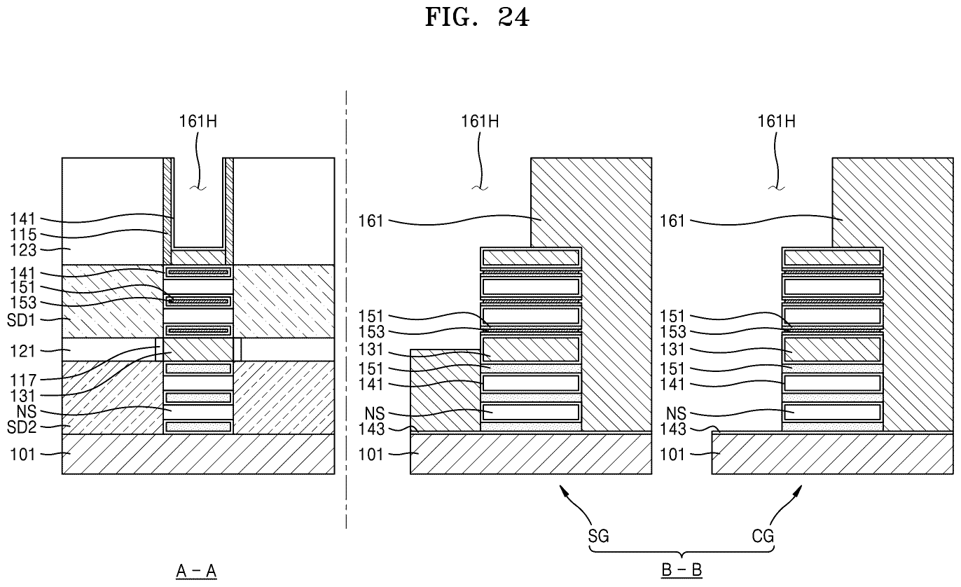

Referring to FIG. 24, different etchings may be performed to a split gate region SG and a common gate region CG.

Based on the drawing, in the split gate region SG, a first recess region 161H may be formed by etching only a left upper portion of the first insulating layer 161 and, in the common gate region CG, the first recess region 161H may be formed by entirely etching a left region of the first insulating layer 161.

Accordingly, a portion of the first insulating layer 161 may exist in a left region of the split gate region SG but an upper surface of an insulating pattern layer 143 including the same material as the gate dielectric films 141 may be exposed in a left region of the common gate region CG.

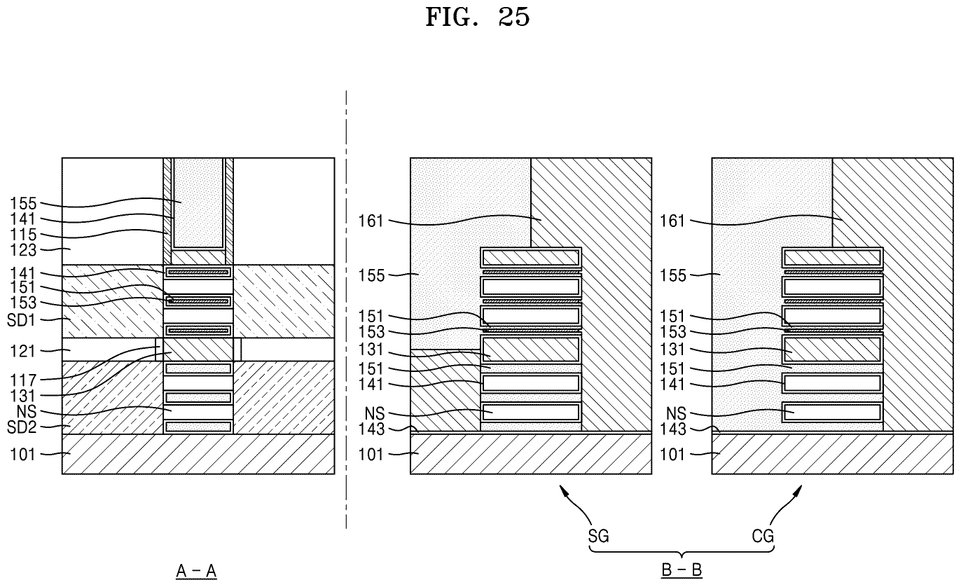

Referring to FIG. 25, a first main gate 155 may be formed so as to entirely fill each of the first recess regions 161H in the split gate region SG and the common gate region CG.

The first main gate 155 may include substantially the same material as the conductive material film 151. In the left region of the split gate region SG, the first main gate 155 may be formed on the portion of the first insulating layer 161 and, in the left region of the common gate region CG, the first main gate 155 may be formed on the upper surface of the insulating pattern layer 143.

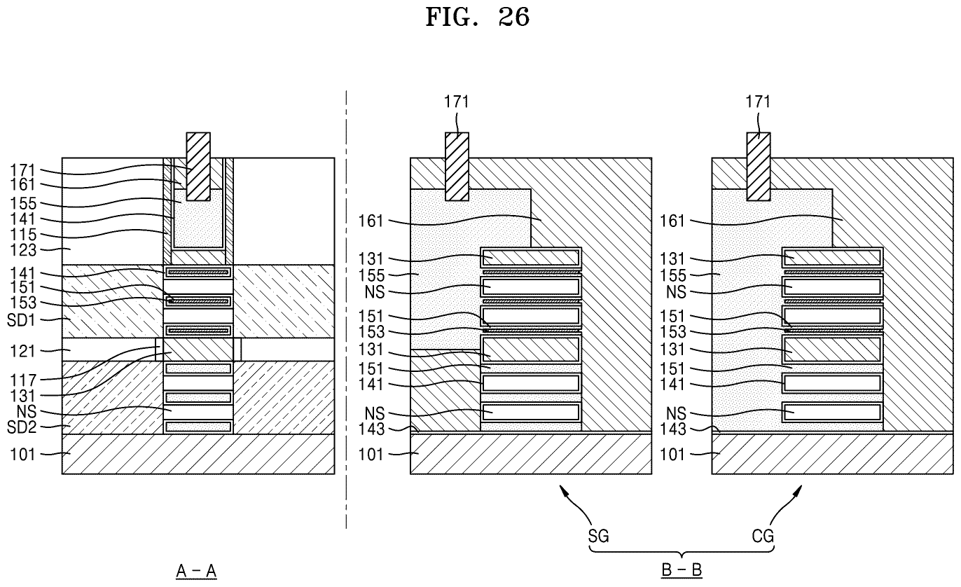

Referring to FIG. 26, a portion of an upper portion of the first main gate 155 may be etched and the first insulating layer 161 may be formed in a region in which the portion has been etched.

Next, a first gate contact 171 digging into a certain portion of the upper portion of the first main gate 155 and contacting the first main gate 155 may be formed. The first gate contact 171 may pass through the first insulating layer 161 and may be connected to the first main gate 155. The first gate contact 171 may be formed in both the split gate region SG and the common gate region CG.

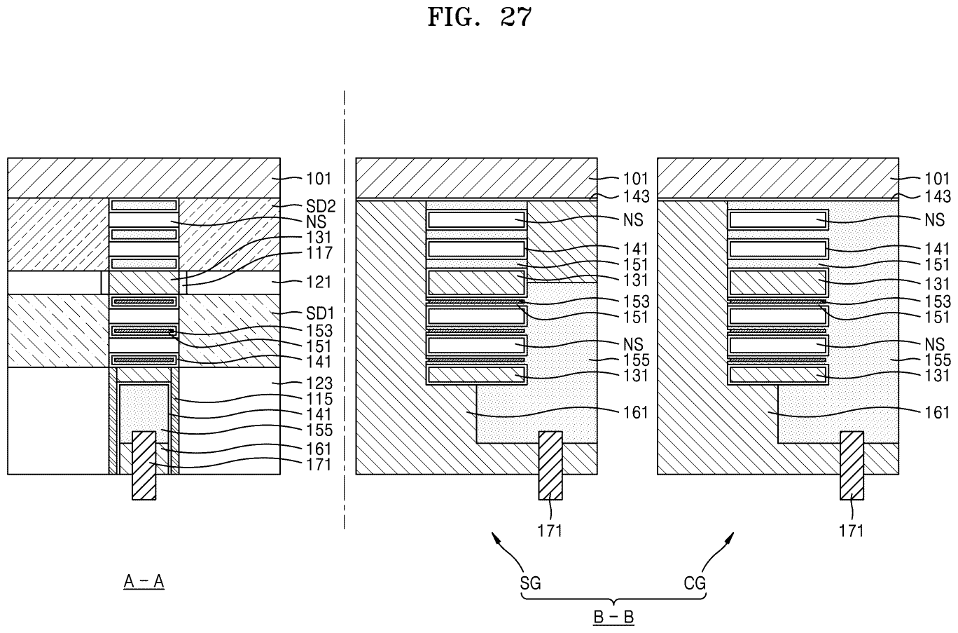

Referring to FIG. 27, the substrate 101 on which the first gate contact 171 is formed may be turned upside down.

Accordingly, based on the drawing, the resultant structure may be described as having a shape in which the substrate 101 is located at the top and the first gate contact 171 digs into a certain portion of a lower portion of the first main gate 155 and contacts the first main gate 155.

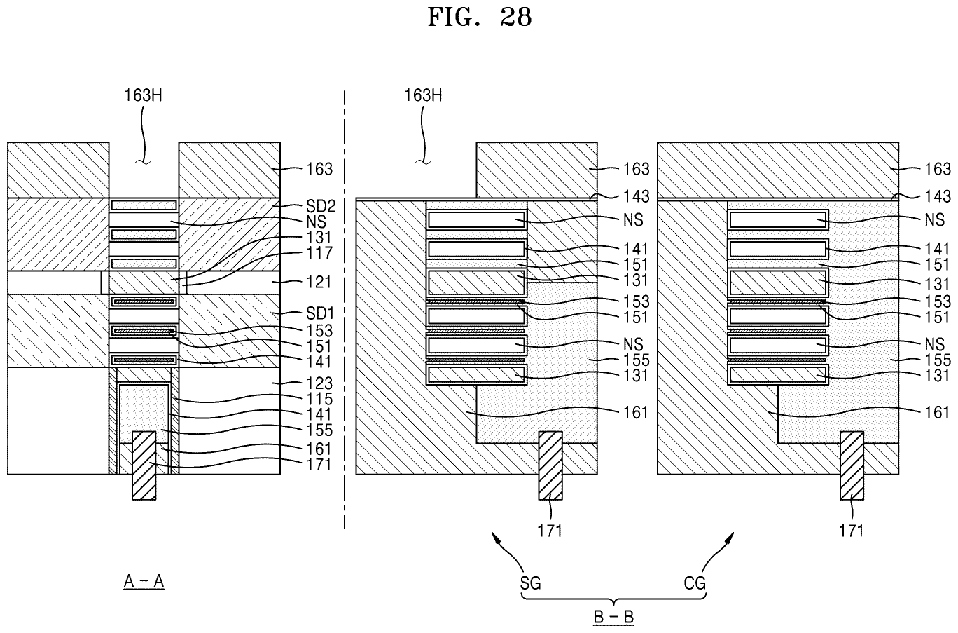

Referring to FIG. 28, the substrate 101 (see FIG. 27) may be removed and different second insulating layers 163 may be formed in the split gate region SG and the common gate region CG.

Based on the drawing, each of the second insulating layers 163 may be formed on the upper surface of the insulating pattern layer 143. In the split gate region SG, a second recess region 163H may be formed by etching a left region of the second insulating layer 163 and, in the common gate region CG, the second insulating layer 163 may be formed but not etched.

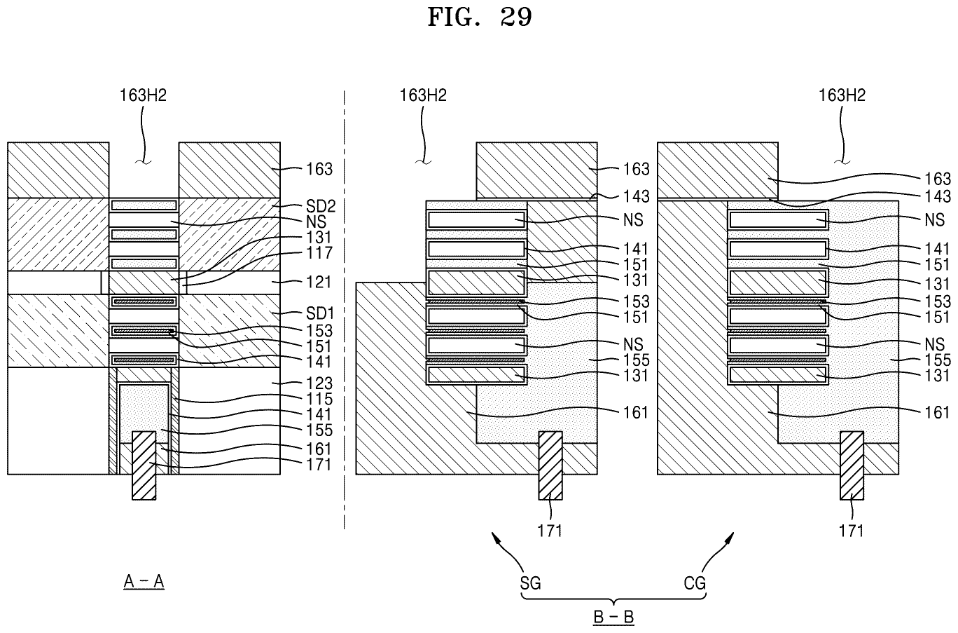

Referring to FIG. 29, different etchings may be performed to the split gate region SG and the common gate region CG.

Based on the drawing, in the split gate region SG, a third recess region 163H2 may be formed by etching the left upper region of the first insulating layer 161 and the insulating pattern layer 143 and, in the common gate region CG, the third recess region 163H2 may be formed by etching a right region of the second insulating layer 163 and the insulating pattern layer 143.

Accordingly, the portion of the first insulating layer 161 may exist in the left region of the split gate region SG, and the first insulating layer 161 may entirely exist in the left region of the common gate region CG.

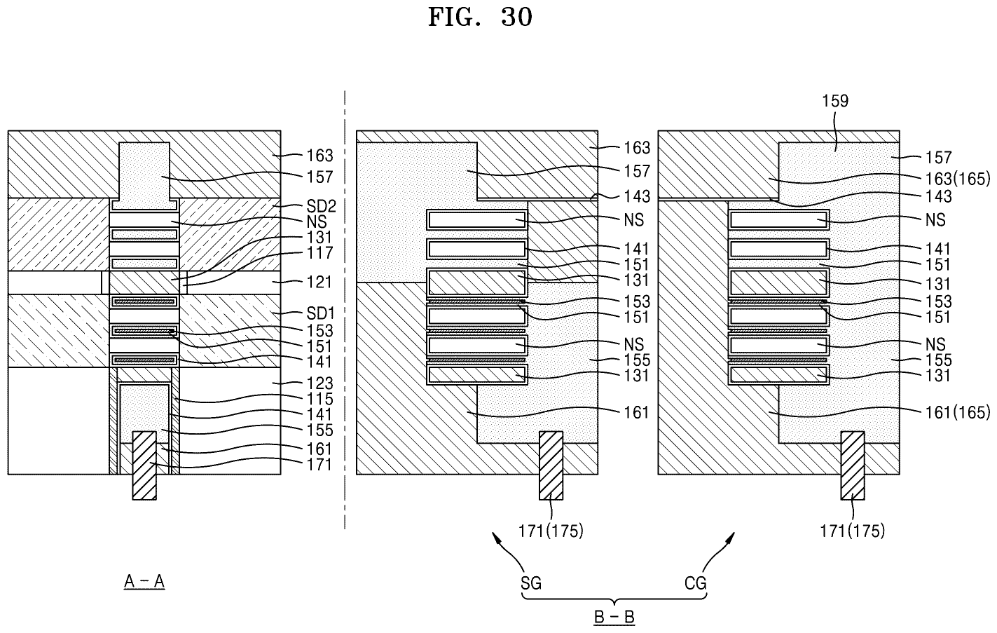

Referring to FIG. 30, a second main gate 157 may be formed so as to fully fill each of the third recess regions 163H2 in the split gate region SG and the common gate region CG.

The second main gate 157 may include substantially the same material as the first main gate 155.

Based on the drawing, in the left region of the split gate region SG, the first main gate 155 may be formed on the portion of the first insulating layer 161 and, in a right region of the common gate region CG, the second main gate 157 may be formed on an upper surface of the first main gate 155.

Next, a portion of an upper portion of the second main gate 157 may be etched and the second insulating layer 163 may be formed in a region in which the portion has been etched.

Accordingly, a third main gate 159 in which the first main gate 155 and the second main gate 157 are merged may be formed in the common gate region CG.

Referring back to FIG. 3, a second gate contact 173 digging into a certain portion of an upper portion of the second main gate 157 and contacting the second main gate 157 may be formed. The second gate contact 173 may pass through the second insulating layer 163 and may be connected to the second main gate 157. The second gate contact 173 may be formed in both the split gate region SG and the common gate region CG.

Through a manufacturing process described above, an integrated circuit device 10 according to an embodiment may be manufactured. The integrated circuit device 10 according to inventive concepts may use a three-dimensional vertical stacked structure in which NMOS transistors and PMOS transistors are stacked in a vertical direction and may thus have a high degree of integration and improved electrical properties.

While aspects of inventive concepts have been particularly shown and described with reference to embodiments thereof, it will be understood that various changes in form and details may be made therein without departing from the spirit and scope of the following claims.

What is claimed is:

1. An integrated circuit device comprising:
a first transistor including a plurality of first nanosheets having a first width in a first horizontal direction, a first gate structure surrounding the plurality of first nanosheets and extending on a first side of the plurality of first nanosheets in a second horizontal direction, and first source/drain regions on opposite sides of the plurality of first nanosheets in the first horizontal direction,
the second horizontal direction being perpendicular to the first horizontal direction,
the first side of the plurality of first nanosheets in the second horizontal direction being opposite a second side of the plurality of first nanosheets in the second horizontal direction; and
a second transistor above the first transistor, the second transistor including a plurality of second nanosheets above the plurality of first nanosheets and having a second width in the first horizontal direction, a second gate structure surrounding the plurality of second nanosheets and extending on a second side of the plurality of second nanosheets in the second horizontal direction, and second source/drain regions on opposite sides of the plurality of second nanosheets in the first horizontal direction,
the second width being equal to the first width,
the second side of the plurality of second nanosheets in the second horizontal direction being opposite a first side of the plurality of second nanosheets in the second horizontal direction, and
the second side of the plurality of second nanosheets in the second horizontal direction being over the second side of the plurality of first nanosheets in the second horizontal direction.

2. The integrated circuit device of claim 1, further comprising:
a first insulating layer under a lower portion of the second gate structure; and
a second insulating layer on an upper portion of the first gate structure, wherein
the first gate structure includes a plurality of first sub-gates and a first main gate,
the plurality of first sub-gates surround the plurality of first nanosheets,
the first main gate contacts the plurality of first sub-gates and extends in the second horizontal direction on the first side of the plurality of first nanosheets in the second horizontal direction,
the second gate structure includes a plurality of second sub-gates and a second main gate,
the plurality of second sub-gates surround the plurality of second nanosheets,
the second main gate contacts the plurality of second sub-gates and extends on the second side of the plurality of second nanosheets in the second horizontal direction,
a thickness of the second insulating layer in a vertical direction is greater than a thickness of the second gate structure over the first gate structure in the vertical direction, and
a thickness of the first insulating layer in the vertical direction is greater than a thickness of the first gate structure in the vertical direction.

3. The integrated circuit device of claim 2, wherein,
in a cross-sectional view, the first main gate of the first gate structure is disposed in a diagonal direction relative to the second main gate of the second gate structure.

4. The integrated circuit device of claim 2, further comprising:
a plurality of gate dielectric films, wherein
each of the plurality of first sub-gates includes double conductive material films,
each of the plurality of second sub-gates includes a single conductive material film, and
the plurality of gate dielectric films are between the plurality of first nanosheets and the plurality of first sub-gates and between the plurality of second nanosheets and the plurality of second sub-gates.

5. The integrated circuit device of claim 4, further comprising:
an insulating pattern layer, wherein
the insulating pattern layer is on an upper surface of an uppermost second sub-gate among the plurality of second sub-gates, and
a material of the insulating pattern layer is the same as a material of the plurality of gate dielectric films.

6. The integrated circuit device of claim 1, further comprising:
a third transistor spaced apart from the first transistor and the second transistor in the first horizontal direction, wherein
the third transistor includes a plurality of third nanosheets having a third width in the first horizontal direction, a third gate structure surrounding the plurality of third nanosheets and extending on one side of the plurality of third nanosheets in the second horizontal direction, and third source/drain regions on opposite sides of the plurality of third nanosheets in the first horizontal direction,
the third width is equal to the first width,
a level of an uppermost surface of the plurality of third nanosheets is equal to a level of an uppermost surface of the plurality of second nanosheets, and
a level of a lowermost surface of the plurality of third nanosheets is equal to a level of a lowermost surface of the plurality of first nanosheets.

7. The integrated circuit device of claim 6, wherein a lowermost nanosheet of the plurality of first nanosheets and a lowermost nanosheet of the plurality of third nanosheets each include dummy nanosheet.

8. The integrated circuit device of claim 6, wherein
a level of an uppermost surface of the third gate structure is the same as a level of an uppermost surface of the second gate structure, and
a level of a lowermost surface of the third gate structure is the same as a level of a lowermost surface of the first gate structure.

9. The integrated circuit device of claim 6, wherein
the first transistor includes a first gate contact in contact with a lower portion of the first gate structure,
the second transistor includes a second gate contact in contact with an upper portion of the second gate structure, and
the third transistor includes third gate contacts in respective contact with an upper portion and a lower portion of the third gate structure.

10. The integrated circuit device of claim 9, wherein,
in a cross-sectional view, the first gate contact is disposed in a diagonal direction relative to the second gate contact, and
the third gate contacts are on a straight line in a vertical direction.

11. An integrated circuit device comprising:
a lower transistor; and
an upper transistor at a higher vertical level than the lower transistor, wherein
the lower transistor includes lower source/drain regions and a lower gate structure between the lower source/drain regions,
the upper transistor includes upper source/drain regions and an upper gate structure between the upper source/drain regions,
the lower gate structure and the upper gate structure divide and share a plurality of nanosheets into an upper portion and a lower portion, and
the plurality of nanosheets are stacked in a vertical direction and have aligned centers.

12. The integrated circuit device of claim 11, wherein the plurality of nanosheets include:
a lowermost dummy nanosheet and a middle dummy nanosheet;
a plurality of lower active nanosheets between the lowermost dummy nanosheet and the middle dummy nanosheet; and
a plurality of upper active nanosheets over the middle dummy nanosheet,
the lower transistor includes the plurality of lower active nanosheets as a lower channel region, and
the upper transistor includes the plurality of upper active nanosheets as an upper channel region.

13. The integrated circuit device of claim 12, wherein
the lower gate structure is in contact with both the lowermost dummy nanosheet and the middle dummy nanosheet,
the upper gate structure is in contact with the middle dummy nanosheet, and
the upper gate structure is not in contact with the lowermost dummy nanosheet.

14. The integrated circuit device of claim 11, wherein,
in a cross-sectional view, the lower transistor includes a lower gate contact in contact with a lower portion of the lower gate structure,
the upper transistor includes an upper gate contact in contact with an upper portion of the upper gate structure, and
the lower gate contact is in disposed in a diagonal direction relative to the upper gate contact.

15. The integrated circuit device of claim 11, further comprising:
an upper insulating layer above the lower gate structure; and
a lower insulating layer under the upper gate structure, wherein,
in a cross-sectional view, a thickness of the upper insulating layer is greater than a thickness of the upper gate structure in the vertical direction above the lower gate structure, and
a thickness of the lower insulating layer is greater than a thickness of the lower gate structure in the vertical direction.

16. An integrated circuit device comprising:
two first transistors spaced apart from each other in a first horizontal direction;
two second transistors spaced apart from each other in the first horizontal direction, the second transistors being above the two first transistors; and
two third transistors spaced apart from each other in the first horizontal direction with the two first transistors and the two second transistors therebetween, wherein
each of the two first transistors includes a plurality of first nanosheets having a first width in the first horizontal direction, a first gate structure surrounding the plurality of first nanosheets and extending on a first side of the plurality of first nanosheets in a second horizontal direction, and first source/drain regions on opposite sides of the plurality of first nanosheets in the first horizontal direction,
the second horizontal direction is perpendicular to the first horizontal direction,
the first side of the plurality of first nanosheets in the second horizontal direction is opposite a second side of the plurality of first nanosheets in the second horizontal direction,
each of the two second transistors includes a plurality of second nanosheets above an underlying one of the plurality of first nanosheets and having a second width in the first horizontal direction, a second gate structure surrounding the plurality of second nanosheets and extending on a second side of the plurality of second nanosheets in the second horizontal direction, and second source/drain regions on opposite sides of the plurality of second nanosheets in the first horizontal direction,
the second width is equal to the first width,
the second side of the plurality of second nanosheets in the second horizontal direction being opposite a first side of the plurality of second nanosheets in the second horizontal direction,
the second side of the plurality of second nanosheets in the second horizontal direction being over the second side of the underlying one of plurality of first nanosheets in the second horizontal direction,
each of the two third transistors includes a plurality of third nanosheets having a third width equal to the first width in the first horizontal direction, a third gate structure surrounding the plurality of third nanosheets and extending on one side of the plurality of third nanosheets in the second horizontal direction, and third source/drain regions on both sides of the plurality of third nanosheets.

17. The integrated circuit device of claim 16, wherein
a level of an uppermost surface of the plurality of third nanosheets is a same level as a level of an uppermost surface of the plurality of second nanosheets, and
a level of a lowermost surface of the plurality of third nanosheets is a same level as a level of a lowermost surface of the plurality of first nanosheets.

18. The integrated circuit device of claim 16, wherein
a level of an uppermost surface of the third gate structure is a same level as a level of an uppermost surface of the second gate structure, and
a level of a lowermost surface of the third gate structure is a same level as a level of lowermost surface of the first gate structure.

19. The integrated circuit device of claim 16, wherein
a number of active nanosheets in the plurality of third nanosheets is equal to a sum of a number of active nanosheets in the plurality of first nanosheets and a number of active nanosheets in the plurality of second nanosheets.

20. The integrated circuit device of claim 16, wherein
the two first transistors include n-channel metal-oxide semiconductor (NMOS) transistors,
the two second transistors include p-channel metal-oxide semiconductor (PMOS) transistors, and
the two first transistors, the two second transistors, and the two third transistors form a flip-flop structure.
